(19) United States
(12) Patent Application Publication
(10) Pub. No.: US 2006/0220156 A1
(43) Pub. Date: Oct. 5, 2006

(54) Semiconductor device and method for manufacturing same

(75) Inventors: Wataru Saito, Kawasaki-shi (JP); Ichiro Omura, Yokohama-shi (JP)

Correspondence Address: C. IRVIN MCCLELLAND;OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Minato-ku (JP)

(21) Appl. No.: 11/358,411

(22) Filed: Feb. 22, 2006

(30) Foreign Application Priority Data
Mar. 30, 2005 (JP) 2005-97164

(51) Int. Cl. H01L 29/76

(52) U.S. Cl. 257/409

(57) ABSTRACT

The present semiconductor device comprises pillar layers formed on a first semiconductor layer, the pillar layers comprising a first semiconductor pillar layer of a first conductivity type and a second semiconductor pillar layer of a second conductivity type which are alternately formed in a first direction along a surface of the first semiconductor layer. A semiconductor base layer of the second conductivity type is selectively formed on the surface of the second semiconductor pillar layer. A guard ring layer of the second conductivity type is formed surrounding the outermost periphery of the semiconductor base layer. The semiconductor base layer has a smaller junction depth than the guard ring layer.

### CROSS REFERENCE TO RELATED APPLICATIONS

This application is based on and claims the benefit of priority from prior Japanese Patent Application No. 2005-97164, filed on Mar. 30, 2005, the entire contents of which are incorporated herein by reference.

### BACKGROUND OF THE INVENTION

1. Field of the Invention

The present invention relates to a semiconductor device and a method for manufacturing the same.

2. Description of the Related Art

The on-resistance of the vertical power MOSFET depends largely on the electrical resistance in the conduction layer (drift layer) portion. The electrical resistance of the drift layer depends on its impurity concentration. A higher impurity concentration can provide a lower on-resistance. A higher impurity concentration, however, will decrease the breakdown voltage of the PN junction between the drift layer and base layer. The impurity concentration thus cannot be higher than a limit determined by the breakdown voltage. A trade-off relation therefore exists between the device breakdown voltage and on-resistance. An improved trade-off is important to provide a semiconductor device with lower power consumption. The trade-off has a limit depending on the device material. Exceeding the limit is required to provide a semiconductor device with low on-resistance.

One known example of the MOSFET to solve this problem has a structure in which the drift layer has a so-called super junction structure. The super junction structure includes a p-type pillar layer and an n-type pillar layer, which are of a vertically-oriented strip, and are alternately embedded in the drift layer in a lateral direction (see, for example, Japanese application patent laid-open publication No. 2003-273355). The super junction structure includes the same charge amount (impurity amount) in the p-type pillar layer and n-type pillar layer to provide a pseudo-non-doped layer which keeps the high breakdown voltage. The structure also carries a current through the highly doped n-type pillar layer to provide the low on-resistance over the material limit.

The super junction structure can thus provide the on-resistance/breakdown voltage trade-off over the material limit. Improvement of this trade-off, i. e., the lower on-resistance, however, requires a smaller lateral interval (pitch) of the super junction structure. The smaller width can facilitate the depletion of the pn junction in the non-conducting state. This allows for the higher impurity concentration in the pillar layer. In this case, in addition to the super junction structure, the MOSFET gate structure formed thereon needs to have the smaller lateral interval (cell pitch), accordingly. A shorter channel is indispensable by providing the smaller cell pitch in the MOSFET gate structure. The p-type base layer with a shallower junction depth can provide the shorter channel. The p-type base layer with a smaller junction depth, however, increases its curvature in the device region end region. This may cause electric field concentration in that region, which can cause destruction of the device. In the conventional device structures, therefore, the MOS gate structure cannot have a small cell pitch which is comparable to the small cell of the super junction structure, thereby providing an insufficiently low on-resistance.

### SUMMARY OF THE INVENTION

A semiconductor device according to one aspect of the present invention comprises: a first semiconductor layer of a first conductivity type; a pillar layer formed on the first semiconductor layer, the pillar layer comprising a first semiconductor pillar layer of a first conductivity type and a second semiconductor pillar layer of a second conductivity type which are alternately formed in a first direction along a surface of the first semiconductor layer; a first main electrode electrically connected to the first semiconductor layer; a semiconductor base layer of the second conductivity type selectively formed on a surface of the second semiconductor pillar layer; a semiconductor diffusion layer of the first conductivity type selectively formed on a surface of the semiconductor base layer; a second main electrode formed in contact with the semiconductor base layer and semiconductor diffusion layer; and a control electrode formed via an insulating film on the semiconductor base layer, semiconductor diffusion layer, and first semiconductor pillar layer, the semiconductor device further comprising a guard ring layer of the second conductivity type formed surrounding an outermost periphery of the semiconductor base layer, and the semiconductor base layer having a smaller junction depth than the guard ring layer.

A method for manufacturing a semiconductor device according to one aspect of the present invention comprises: forming on a first semiconductor layer of a first conductivity type a second semiconductor layer having a lower impurity concentration than the first semiconductor layer; forming a plurality of equally spaced trenches in the second semiconductor layer; embedding a semiconductor layer of a second conductivity type in the trench to form pillar layers comprising a first semiconductor pillar layer of the first conductivity type and a second semiconductor pillar layer of the second conductivity type which are alternately formed on the first semiconductor layer; forming on the pillar layers a guard ring layer of the second conductivity type surrounding a device region, the guard ring layer having a first junction depth; forming in the device region a semiconductor base layer having a second junction depth smaller than the first junction depth.

A method for manufacturing a semiconductor device according to one aspect of the present invention comprises: forming on a first semiconductor layer of a first conductivity type a second semiconductor layer having a lower impurity concentration than the first semiconductor layer; forming on the second semiconductor layer a guard ring layer of a second conductivity type surrounding a device region, the guard ring layer having a first junction depth; forming a plurality of equally spaced trenches in the second semiconductor layer including a position of the guard ring layer; embedding a semiconductor layer of the second conductivity type in the trench to form pillar layers comprising a first semiconductor pillar layer of the first conductivity type and a second semiconductor pillar layer of the second conductivity type which are alternately formed on the first semiconductor layer; forming on a surface of the pillar layers a semiconductor base layer having a second junction depth smaller than the first junction depth.

### BRIEF DESCRIPTION OF THE DRAWINGS

FIG. 1 is a plan view of the device structure of the vertical power MOSFET with the super junction structure according to the first embodiment of the present invention.

FIG. 2 is a cross sectional view along the line A-A in FIG. 1.

FIG. 3 illustrates the effect of the p-type guard ring layer 10 having a junction depth larger than the p-type base layer 3.

FIG. 4 is a process chart of the manufacturing process of the vertical power MOSFET in FIG. 1.

FIG. 5 is another process chart of the manufacturing process of the vertical power MOSFET in FIG. 1.

FIG. 6 is another process chart of the manufacturing process of the vertical power MOSFET in FIG. 1.

FIG. 7 is another process chart of the manufacturing process of the vertical power MOSFET in FIG. 1.

FIG. 8 is another process chart of the manufacturing process of the vertical power MOSFET in FIG. 1.

FIG. 9 is a cross sectional view of the device structure of the vertical power MOSFET with the super junction structure according to the second embodiment of the present invention.

FIG. 10 is a cross sectional view of the device structure of the vertical power MOSFET with the super junction structure according to the third embodiment of the present invention.

FIG. 11 is a cross sectional view of the device structure of the vertical power MOSFET with the super junction structure according to the fourth embodiment of the present invention.

FIG. 12 is a process chart of the manufacturing process of the vertical power MOSFET in FIG. 11.

FIG. 13 is another process chart of the manufacturing process of the vertical power MOSFET in FIG. 11.

FIG. 14 is another process chart of the manufacturing process of the vertical power MOSFET in FIG. 11.

FIG. 15 is another process chart of the manufacturing process of the vertical power MOSFET in FIG. 11.

### DETAILED DESCRIPTION OF THE EMBODIMENTS

Embodiments of the present invention will be described below with reference to drawings. Note that the following embodiments will be described with respect to a MOSFET as an example in which the first conductivity type is the n-type and the second conductivity type is the p-type.

### FIRST EMBODIMENT

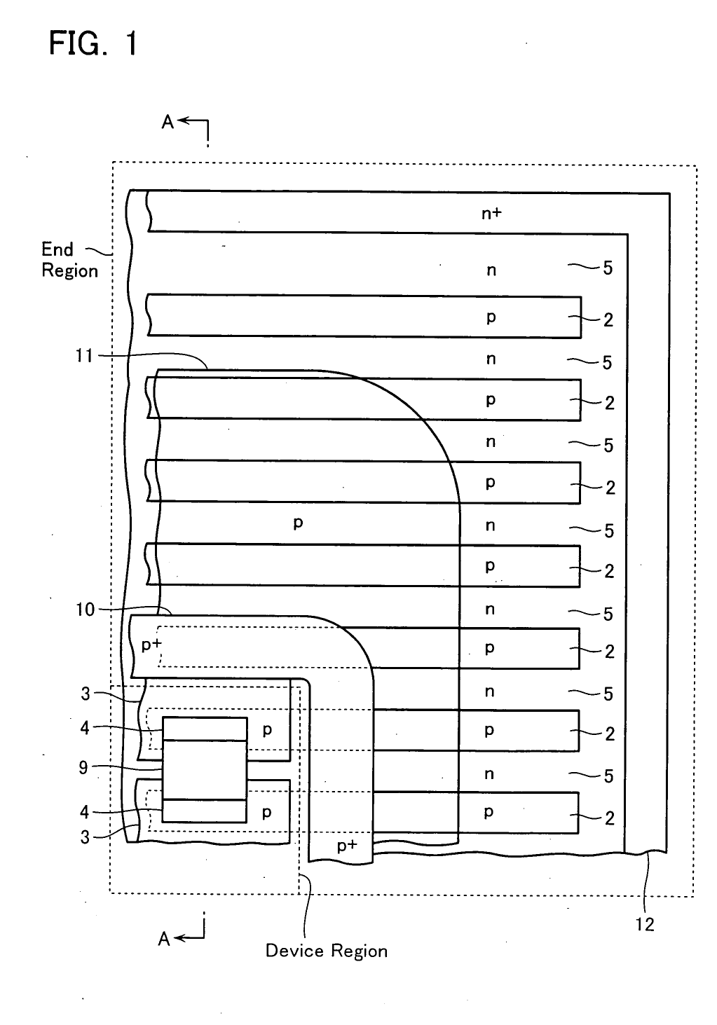

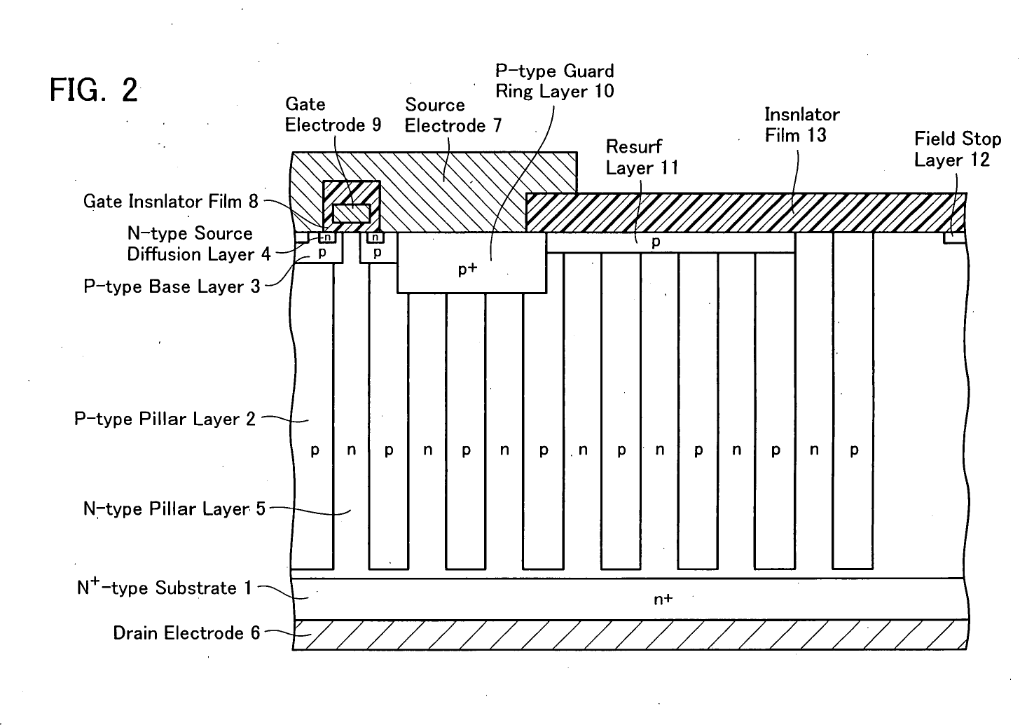

FIG. 1 is a schematic plan view of the configuration of the power MOSFET according to the first embodiment of the present invention. FIG. 2 is a cross sectional view along the line A-A in FIG. 2. The MOSFET has a super junction structure formed over the n⁺-type substrate 1 which functions as the drain layer. The super junction structure includes an n-type pillar layer 5 and a p-type pillar layer 2, which have a cross section of a vertically-oriented strip and are formed alternately in the lateral direction (the first direction) along the surface of the n⁺-type substrate 1. Formed under the n⁺-substrate 1 is a drain electrode 6 common to a plurality of MOSFETs. Note that although the example in FIG. 2 shows the p-type pillar layer 2 which is not contact with the n⁺-type substrate 1, the layer 2 can be configured to be in contact with the substrate 1.

A p-type base layer 3 in a stripe shape is selectively formed on the surface of the p-type pillar layer 2. An n-type source diffusion layer 4 in a stripe shape is selectively formed on the surface of the p-type base layer 3.

A gate electrode 9 in a stripe shape is formed via a gate insulation film 8 on the n-type source diffusion layer 4, p-type base layer 3, and n-type pillar layer 5. With reference to FIG. 2, the gate insulator film 8 and gate electrode 9 can be commonly formed on the adjacent two p-type base layers 3 opposed across the one n-type pillar layer 5. The gate insulator film 8 may be, for example, a silicon oxide film with a thickness of about 0.1 um.

A source electrode 7 common to each MOSFET connects to the p-type base layer 3 and n-type source diffusion layer 4. The gate insulator film 8 or the like isolates the source electrode 7 from the gate electrode 9. Formed around the outermost p-type base layer of the plurality of p-type base layers 3 is a p-type guard ring layer 10 having a junction depth larger than the p-type base layer 3. The p-type guard ring layer 10 is formed in an earlier manufacturing process than the p-type base layer 3. The p-type guard ring layer 10 preferably has a higher impurity concentration than the p-type base layer 3. The impurity concentration in the p-type base layer 3 usually depends on the gate threshold voltage. The guard ring layer 10 formed around the device region, however, has no relation to the gate threshold voltage. The impurity concentration in the guard ring layer 10 can thus be any value. A higher impurity concentration is preferable for a deeper diffusion layer. An avalanche breakdown during high voltage application drives holes generated in the end region into the guard ring layer 10. To drain the generated holes immediately, the guard ring layer 10 preferably has a lower resistance, i. e., a higher impurity concentration. This allows for the high avalanche withstanding capability.

Note that in the power MOSFET in this embodiment, the super junction structure including the p-type pillar layer 2 and n-type pillar layer 5 is formed in the device region as well as in the end region around the device region, and further a p-type resurf layer 11 is formed over the super junction structure in the end region. Moreover, a field-stop layer 12 is formed at the periphery of the end region.

According to this embodiment, when the MOSFET is non-conducting, the depletion layer extends laterally in the end region, thereby helping to decrease the electric field concentration in the p-type guard ring layer 10.

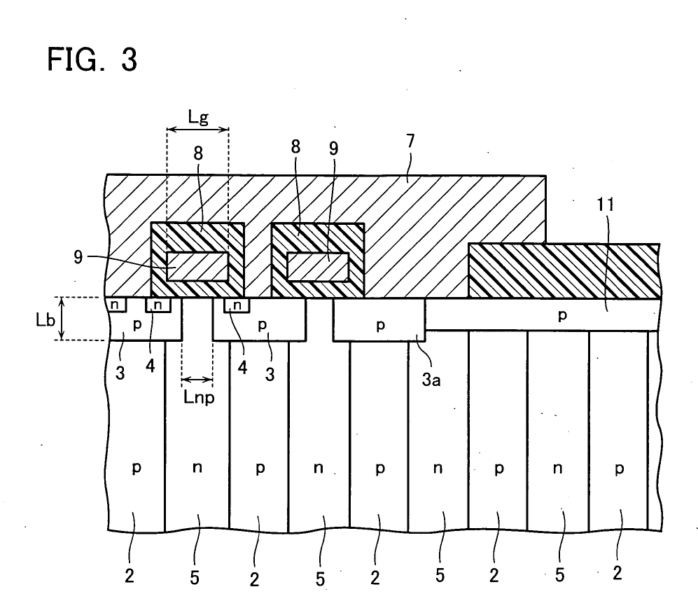

With reference to FIG. 3, a description is given of the effect of the p-type guard ring layer 10 having a junction depth larger than the p-type base layer 3. A smaller lateral interval (cell pitch) of the pn pillar layers 2 and 5 for a higher impurity concentration in the pillars in the super junction structure requires a smaller cell pitch of the MOSFET gate structure. A smaller cell pitch of the MOSFET gate structure may simply be realized by a shorter gate length Lg (FIG. 3).

A simply shorter gate length Lg, however, will decrease the distance Lnp (FIG. 3) between the p-type base layers 3. This will increase the resistance of the n-type pillar layer 5 between the p-type base layers 3. A smaller junction depth Lb of the p-type base layer 3 is thus needed to decrease the cell pitch with a suppressed increase in the resistance in the MOSFET gate portion (that is, with ensuring the sufficient distance Lnp). A smaller junction depth Lb of the p-type base layer 3, however, will provide a smaller curvature radius (larger curvature) of the end portion of the p-type base layer 3. This causes the electric field concentration particularly in the p-type base layer 3a which functions as the guard ring layer in the device end region. This may decrease the breakdown voltage.

This embodiment therefore decreases the depth of the p-type base layer 3 in the device region, and provides around the outermost p-type base layer a p-type guard ring layer 10 having a junction depth larger than the p-type base layer 3. This can determine the junction depth Lb of the p-type base layer 3 without taking into account the electric field concentration in the device end portion. This can provide a smaller cell pitch of the MOSFET gate structure adapted to the cell pitch of the super junction structure. The deep guard ring layer 10 can provide a breakdown voltage of the end region which is at the same level as the breakdown voltage of the device region. This can provide the lower on-resistance as well as the high avalanche withstanding capability. A breakdown voltage of the end region which is lower than the breakdown voltage of the device region will cause the avalanche breakdown only in the end region during high voltage application. This drives the avalanche current only in the end region, so that even a small amount of current may cause destruction of the device. This embodiment therefore provides the deep guard ring layer 10 around the device region. The guard ring layer 10 can make the breakdown voltage of the end region at the same level as the breakdown voltage of the device region. This can cause the avalanche breakdown in the end region as well as in the device region during high voltage application, thereby avoiding destruction of the device even for the large avalanche current. This then allows for the high avalanche withstanding capability.

In the above-described embodiment, the high avalanche withstanding capability can still be provided by a breakdown voltage of the device region being lower than the breakdown voltage of the end region, which can be implemented. More specifically, the implementation can be done, for example, by forming an n-type layer having a higher concentration than the n-type pillar layer 5 between the adjacent p-type base layers 3 in the device region. In this case, the n-type layer formed between the p-type base layers 3 can provide a lower resistance between the p-type base layers 3, which can decrease the on-resistance.

Note that as shown in FIG. 1, it is preferable in terms of the low on-resistance that both of the super junction structure and MOSFET gate structure are formed in a stripe shape, and their stripes are parallel and have substantially the same cell pitch. It is also possible that both stripes are orthogonal to each other, and that the super junction structure and MOS gate structure have independently variable cell pitches. Both stripes which are orthogonal to each other will, however, provide a higher spreading resistance under the p-type base layer, which causes the higher on-resistance. It is thus preferable to form the stripes in parallel as shown in FIG. 1.

The trench gate structure being used as the MOSFET gate structure can relatively easily provide the smaller cell pitch of MOSFET. The trench gate structure, however, may provide, during high voltage application, the avalanche breakdown point on the trench bottom. This may decrease the reliability of the gate insulation film and decrease the avalanche withstanding capability. It is thus preferable to use the planar gate structure as the MOSFET gate structure in this embodiment.

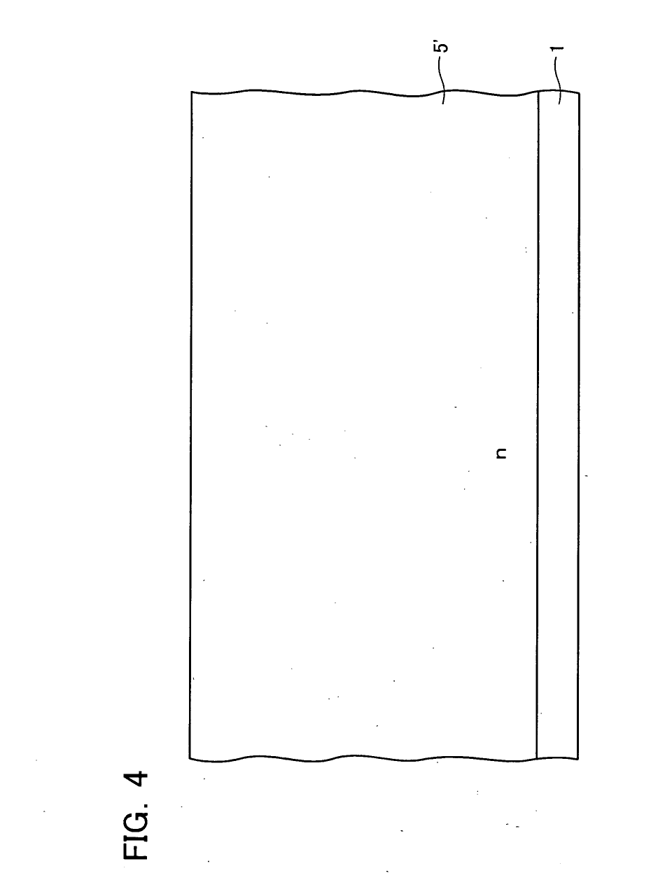

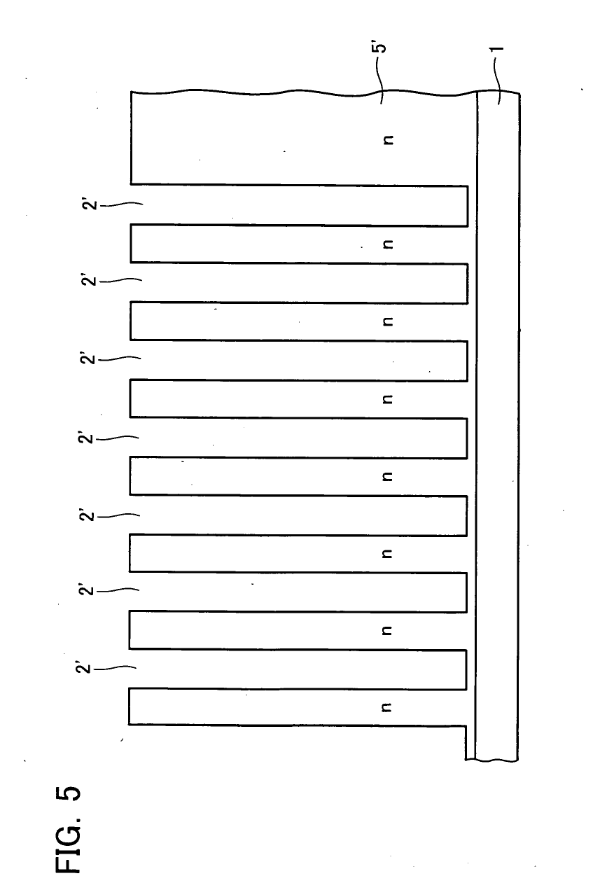

Referring to FIGS. 4 to 8, a description is given of the manufacturing processes of the power MOSFET according to the first embodiment. First, as shown in FIG. 4, an n-type layer 5′ is epitaxially grown on the n⁺-type substrate 1. The n-type layer 5′ has a lower impurity concentration than the substrate 1. Next, as shown in FIG. 5, a deep trench 2′ is formed in the n-type layer 5′ by photolithography and RIE (Reactive Ion Etching), the trench 2′ reaching at least near the bottom of the n-type layer 5′.

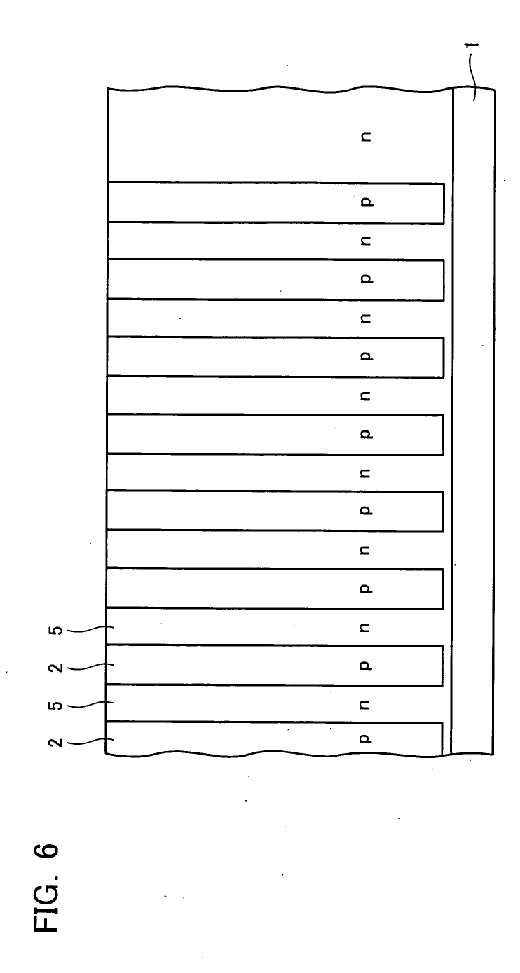

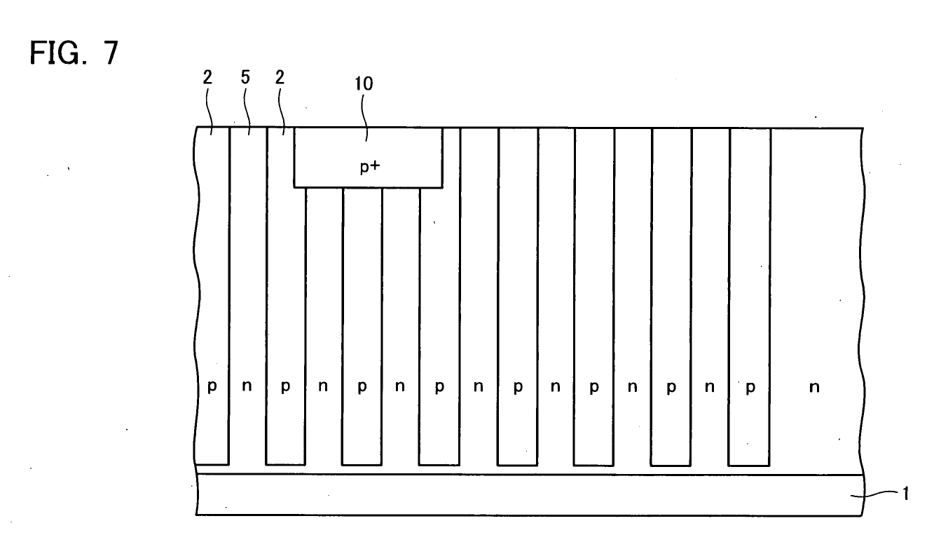

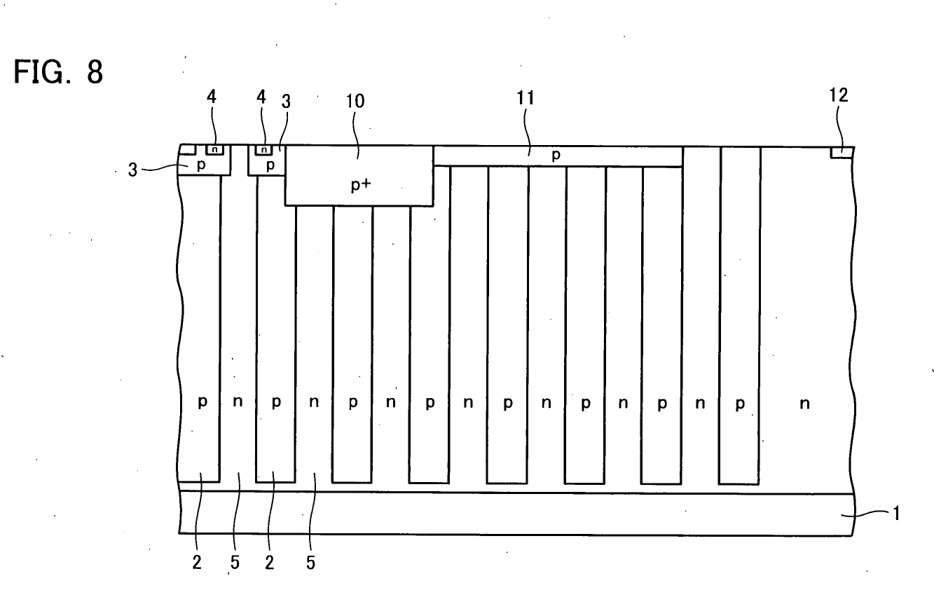

Then, as shown in FIG. 6, the p-type silicon layers are embedded in the trenches 2′ by CVD, CMP, and the like, thereby forming the super junction structure which includes the n-type pillar layer 5 and p-type pillar layer 2. Then, as shown in FIG. 7, the p-type guard ring layer 10 is first formed by photolithography and ion implantation with a junction depth of, for example, about 3 um. Then, as shown in FIG. 8, the p-type base layer 3 is formed by photolithography, ion implantation, and the like, with a junction depth of, for example, about 1.5 um. The n-type source diffusion layer 4, resurf layer 11, and the like are then formed by photolithography, ion implantation, and the like, and then the electrodes 6, 7, 9, and the like are formed, thereby completing the power MOSFET shown in FIG. 1 and FIG. 2.

### SECOND EMBODIMENT

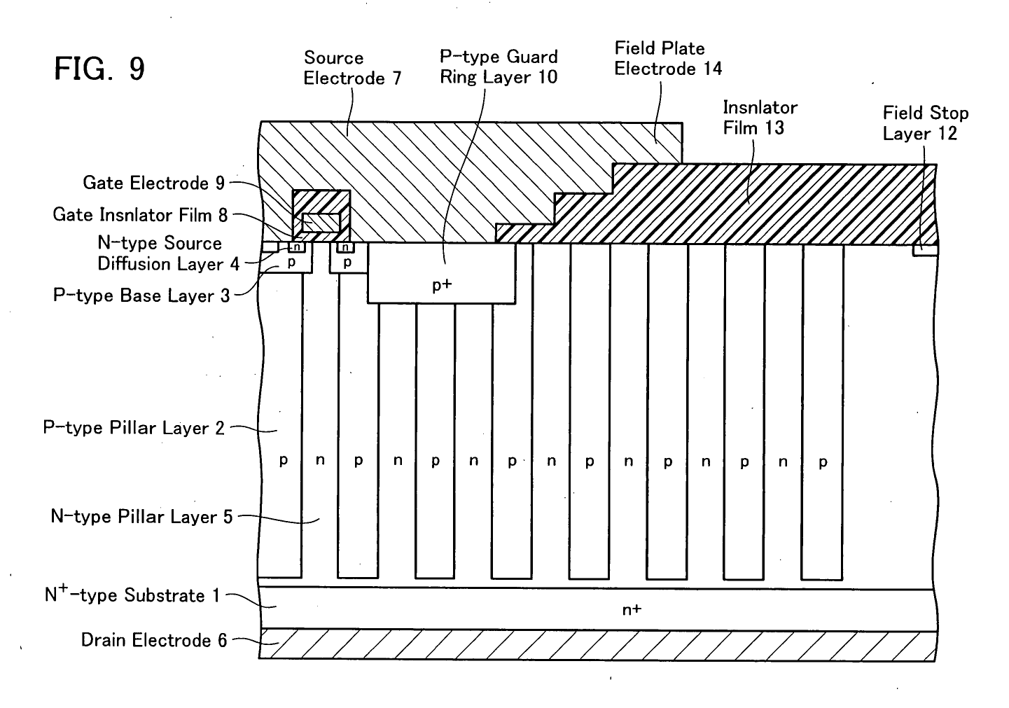

FIG. 9 is a schematic cross sectional view of the configuration of the power MOSFET according to the second embodiment of the present invention. The plan view is omitted here because it is substantially the same as FIG. 1 except for the resurf layer 11. In the power MOSFET according to this embodiment, an insulator film 13 resides on the surface of the super junction structure formed in the end region. A field plate electrode 14 resides on the insulator film 13, the field plate electrode 14 being connected to the source electrode 7. Consequently, as in the resurf structure in the first embodiment (FIG. 1), the depletion layer extends immediately laterally in the end region when the MOSFET is non-conducting, thereby helping to increase the breakdown voltage.

### THIRD EMBODIMENT

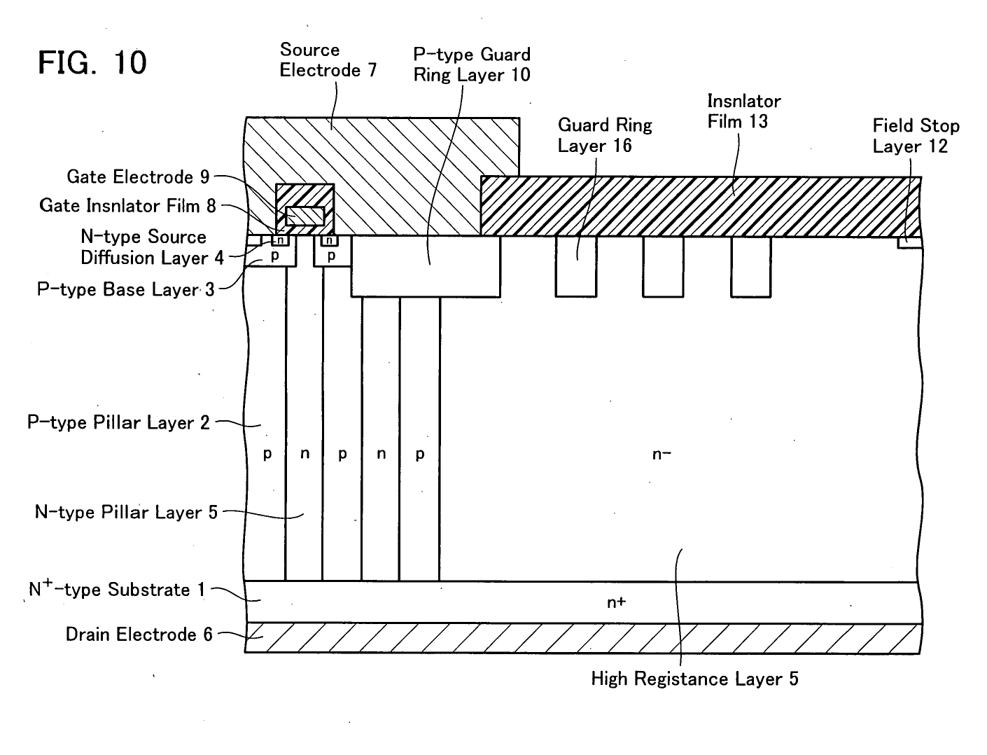

FIG. 10 is a schematic cross sectional view of the configuration of the power MOSFET according to the third embodiment of the present invention. This embodiment differs from the above embodiments in that the super junction structure is not formed in the end region, and alternatively, a high resistance layer 15 is formed, and a p-type guard ring layer 16 is formed on the high resistance layer 15. Also in this embodiment, when the MOSFET is non-conducting, the depletion layer extends laterally along the guard ring layer 16, thereby helping to increase the breakdown voltage.

### FOURTH EMBODIMENT

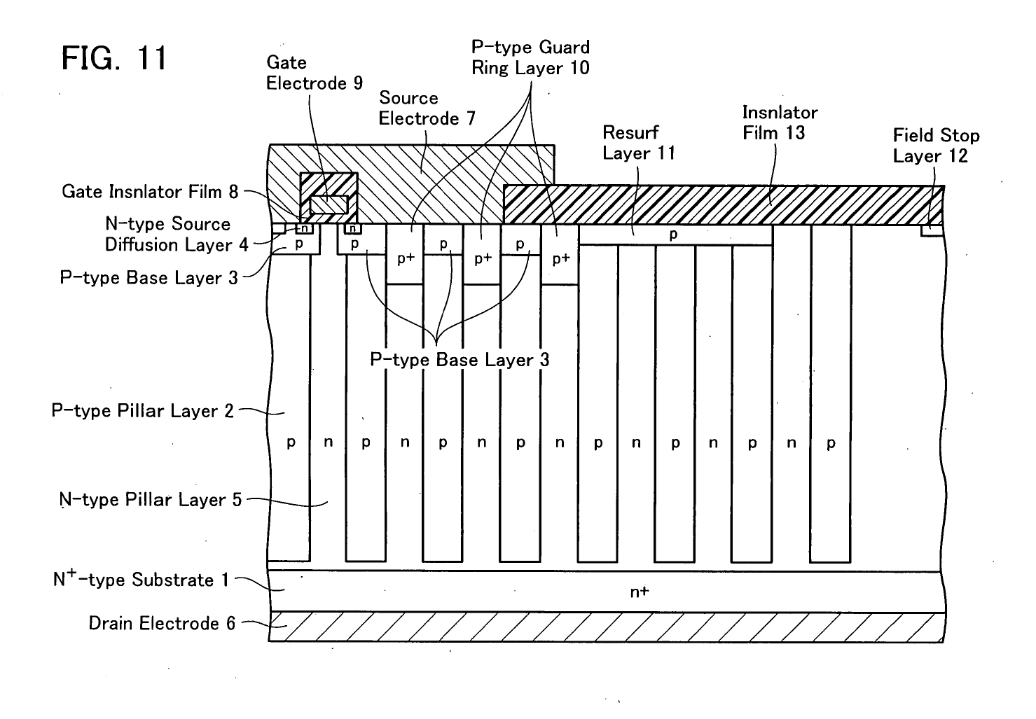

FIG. 11 is a schematic cross sectional view of the configuration of the power MOSFET according to the fourth embodiment of the present invention. This embodiment differs from the above embodiments in that the p-type guard ring layers 10 having a larger junction depth than the p-type base layers 3 are separately provided in the end region with the p-type base layer 3 disposed between the layers 10. A plurality of separate p-type guard ring layers 10 connected by the p-type base layers 3 allow the depletion layer to extend laterally in that portion when the MOSFET is non-conductive, thereby helping to decrease the electric field concentration to provide the high breakdown voltage. This embodiment also differs from the above embodiments in that the p-type guard ring layers 10 are formed before the super junction structure is formed.

Note that although FIG. 11 shows an example where the super junction structure is formed up to the end region, and the resurf layer 11 is formed, it should be appreciated that the present invention is not limited thereto. It should be understood, for example, that as in the above embodiments, the resurf layer 11 may be replaced by the field plate electrode, and the super junction structure may not be formed in the end region and alternatively, the guard ring layers may be multiply-formed.

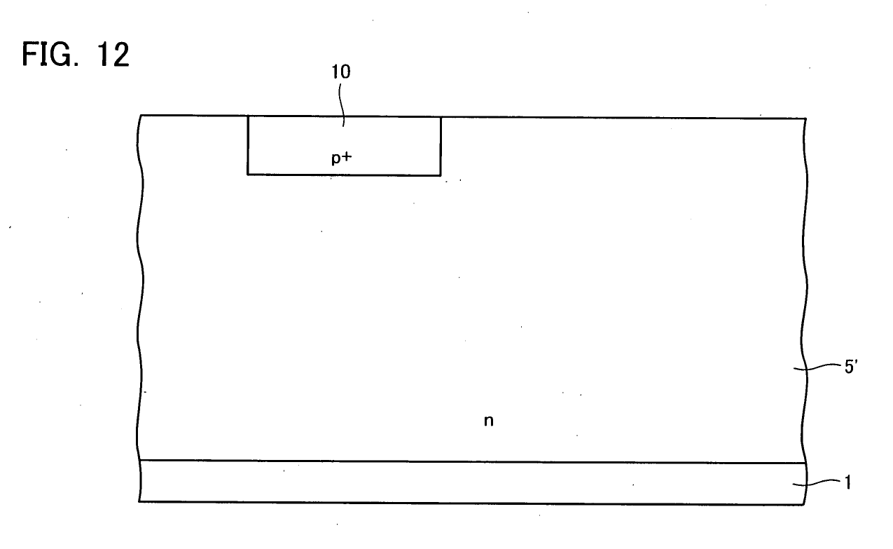

Referring to FIGS. 12 to 15, a description is given of the manufacturing processes of the power MOSFET according to the fourth embodiment. First, as shown in FIG. 12, the n-type layer 5′ is epitaxially grown on the n⁺-type substrate 1. The n-type layer 5′ has a lower impurity concentration than the substrate 1. Then a p-type layer for the p-type guard ring layer 10 is then selectively diffused to a depth of about 3 um.

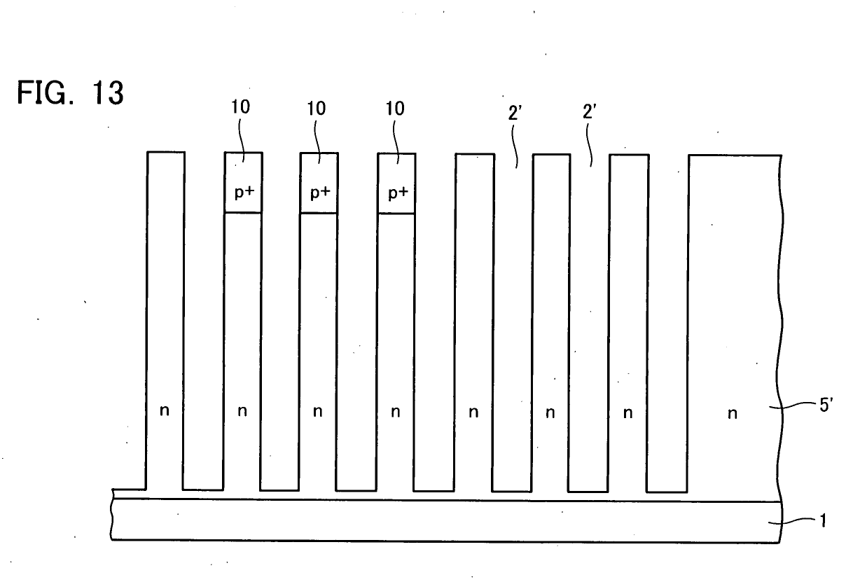

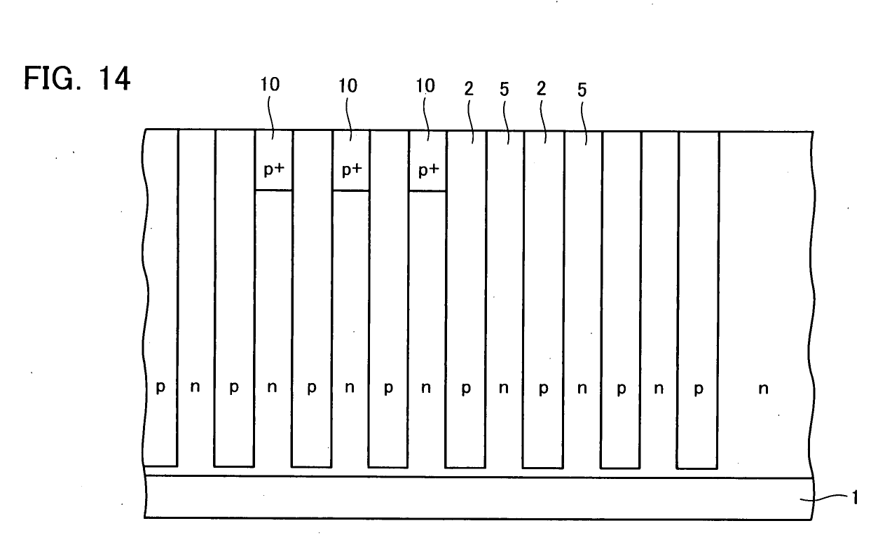

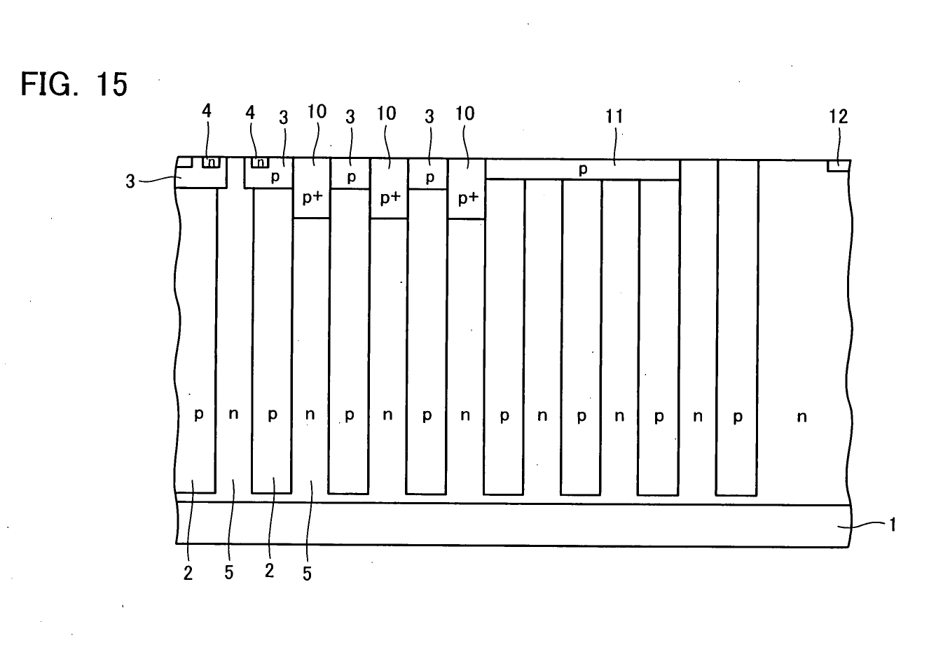

Next, as shown in FIG. 13, the deep trenches 2′ reaching near the bottom of the n-type layer 5′ are formed by photolithography and RIE (Reactive Ion Etching), including the positions of the p-type layers. Then, as shown in FIG. 14, the p-type silicon layers are embedded in the trenches 2′ by CVD, CMP, and the like, thereby forming the super junction structure which includes the n-type pillar layer 5 and p-type pillar layer 2. More specifically, this embodiment forms the super junction structure in a step later than that for the p-type guard ring layer 10, so that the super junction structure has a less diffusion of the impurity than in the first to third embodiments, thereby providing the low on-resistance MOSFET. Then, as shown in FIG. 15, the p-type base layer 3 is selectively formed by photolithography, ion implantation, and the like, with a junction depth of, for example, about 1.5 um. Then, the n-type source diffusion layer 4, resurf layer 11, and the like are formed by photolithography, ion implantation, and the like, and then the electrodes 6, 7, 9 and the like are formed, thereby completing the power MOSFET shown in FIG. 11.

Thus, although the present invention has been described with respect to the first to fourth embodiments thereof, the invention is not limited to those embodiments. For example, although the description has been given with respect to the case where the first conductivity type is the n-type and the second conductivity type is the p-type, the first conductivity type may be the p-type and the second conductivity type may be the n-type. Also, for example, the plane pattern of the gate part or super junction structure of the MOSFET is not limited to the stripe, and may be a lattice or zigzag. The manufacturing processes of the super junction structure are not limited to the above-mentioned embodiments, and may include a variety of processes such as the repetition of a plurality of ion implantations and epitaxial growth, the trench formation followed by the embedding growth, and the trench formation followed by the ion implantation in the sidewall of the trench.

Although the description has been given with respect to the MOSFET using silicon (Si) as the semiconductor, the semiconductor may be, for example, a compound semiconductor such as silicon carbide (SiC) or gallium nitride (GaN), or a wide band gap semiconductor such as diamond. Although the description has been given with respect to the MOSFET having the super junction structure, the present invention applies to any device having the super junction structure, such as the combined device including SBD or MOSFET and Schottky barrier diode, SIT, or IGBT.

What is claimed is:

1. A semiconductor device comprising:
a first semiconductor layer of a first conductivity type;
a pillar layer formed on the first semiconductor layer, the pillar layer comprising a first semiconductor pillar layer of a first conductivity type and a second semiconductor pillar layer of a second conductivity type which are alternately formed in a first direction along a surface of the first semiconductor layer;
a first main electrode electrically connected to the first semiconductor layer;
a semiconductor base layer of the second conductivity type selectively formed on a surface of the second semiconductor pillar layer ;
a semiconductor diffusion layer of the first conductivity type selectively formed on a surface of the semiconductor base layer;
a second main electrode formed in contact with the semiconductor base layer and semiconductor diffusion layer; and
a control electrode formed via an insulating film on the semiconductor base layer, semiconductor diffusion layer, and first semiconductor pillar layer,
the semiconductor device further comprising a guard ring layer of the second conductivity type formed surrounding an outermost periphery of the semiconductor base layer, and
the semiconductor base layer having a smaller junction depth than the guard ring layer.

2. The semiconductor device according to claim 1, wherein the guard ring layer has a higher impurity concentration than the semiconductor base layer.

3. The semiconductor device according to claim 2, wherein the guard ring layer is connected to the second main electrode.

4. The semiconductor device according to claim 3, wherein an insulating gate structure comprising the first semiconductor pillar layer, semiconductor base layer, semiconductor diffusion layer, insulating film, and control electrode is a planar gate structure.

5. The semiconductor device according to claim 1, wherein the first semiconductor pillar layer, the second semiconductor pillar layer, and the control electrode are formed in a stripe shape.

6. The semiconductor device according to claim 5, wherein the stripe shape of the first semiconductor pillar layer and the second semiconductor pillar layer is in parallel with the stripe shape of the control electrode.

7. The semiconductor device according to claim 1, wherein the pillar layers are formed inside and outside the guard ring layer.

8. The semiconductor device according to claim 7, further comprising a semiconductor layer of the second conductivity type formed on the pillar layer located outside the guard ring layer.

9. The semiconductor device according to claim 7; wherein a field plate electrode is formed via an insulating film on the pillar layer located outside the guard ring layer, and the field plate electrode is connected to the second main electrode.

10. The semiconductor device according to claim 1, wherein the pillar layer is formed only inside the guard ring layer, and a high resistance layer having a higher resistance than the first semiconductor pillar layer is formed on the first semiconductor layer outside the guard ring layer.

11. The semiconductor device according to claim 10, wherein a plurality of guard ring layers are multiply-formed on the high resistance layer.

12. The semiconductor device according to claim 1, wherein a plurality of the guard ring layers are formed with the semiconductor base layer disposed between the guard ring layers.

13. A method for manufacturing a semiconductor device comprising:
forming on a first semiconductor layer of a first conductivity type a second semiconductor layer of the first conductivity type having a lower impurity concentration than the first semiconductor layer;
forming a plurality of equally spaced trenches in the second semiconductor layer;
embedding a semiconductor layer of a second conductivity type in the trench to form pillar layers comprising a first semiconductor pillar layer of the first conductivity type and a second semiconductor pillar layer of the second conductivity type which are alternately formed on the first semiconductor layer;
forming on the pillar layers a guard ring layer of the second conductivity type surrounding a device region, the guard ring layer having a first junction depth;
forming in the device region a semiconductor base layer having a second junction depth smaller than the first junction depth.

14. A method for manufacturing a semiconductor device comprising:
forming on a first semiconductor layer of a first conductivity type a second semiconductor layer of the first conductivity type having a lower impurity concentration than the first semiconductor layer;
forming on the second semiconductor layer a guard ring layer of a second conductivity type surrounding a device region, the guard ring layer having a first junction depth;
forming a plurality of equally spaced trenches in the second semiconductor layer, inducing a position of the guard ring layer;
embedding a semiconductor layer of the second conductivity type in the trench to form pillar layers comprising a first semiconductor pillar layer of the first conductivity type and a second semiconductor pillar layer of the second conductivity type which are alternately formed on the first semiconductor layer;
forming on a surface of the pillar layers a semiconductor base layer having a second junction depth smaller than the first junction depth.
